(19) United States
(12) Patent Application Publication
(10) Pub. No.: US 2008/0049484 A1
(43) Pub. Date: Feb. 28, 2008

(54) SEMICONDUCTOR MEMORY DEVICE WHERE WRITE AND READ DISTURBANCES HAVE BEEN IMPROVED

(76) Inventor: Takahiko SASAKI, Tokyo (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/828,593

(22) Filed: Jul. 26, 2007

(30) Foreign Application Priority Data
Jul. 28, 2006 (JP) 2006-206797

(51) Int. Cl. G11C 5/00

(52) U.S. Cl. 365/72

(57) ABSTRACT

A data write transfer gate and a write driver transistor are connected to a data latch circuit for storing data, thereby producing a write data path. The data path is controlled by a word line and a data write bit line. In addition, a read drive transistor and a read transfer gate are connected to the latch circuit, thereby producing a read data path. The data path is controlled by a word line, a read bit line, and the data in the data latch circuit.

### CROSS-REFERENCE TO RELATED APPLICATIONS

This application is based upon and claims the benefit of priority from prior Japanese Patent Application No. 2006-206797, filed Jul. 28, 2006, the entire contents of which are incorporated herein by reference.

### BACKGROUND OF THE INVENTION

1. Field of the Invention

This invention relates to a semiconductor memory device, and more particularly to the configuration of a memory cell of a static random access memory (SRAM) and the configuration of a memory cell array.

2. Description of the Related Art

With the recent improvement in the integration degree of semiconductor memory devices, transistors constituting memory cells have been miniaturized further. In parallel with the miniaturization, an increase in the variation of the threshold value in the transistors has become a serious problem. An SRAM where a memory cell is composed of six transistors has been known. In the memory cell, because of the effect of a variation in the threshold value of the transistors, a so-called static noise margin (SNM) decreases, which causes a problem: a memory cell with an insufficient SNM appears. In a memory cell where the SNM is low and the stability of data is low, there is a possibility that a write disturbance and a read disturbance will occur. A write disturbance and a read disturbance are phenomenon where, when a certain word line is selected in writing data into a memory cell or reading the data from a memory cell, the transfer gates of all the memory cells connected to the word line go on, inverting the stored states of the data storage latch circuits, which destroys the data.

There are two major causes of variation in the threshold value giving rise to a decrease in the SNM. One of them is a variation in the transistor size and the other is a fluctuation in the density of dopant.

A measure to decrease a variation in the threshold value from the viewpoint of worked surfaces is to devise the layout of a memory cell. For example, the transistors constituting a memory cell are divided into two groups. Then, for example, a polysilicon gate, a contact, a source region/a drain region/a gate region (hereinafter, referred to as an active area), metal interconnects, and others are arranged in such a manner that the divided two groups of transistors are symmetric with respect to a point. In a memory cell having such a layout (hereinafter, referred to as a point-symmetric cell), to reduce variation in the threshold value of transistors, the active areas and gate electrodes of the individual transistors are arranged and formed in almost a straight line. In a memory cell array where a large number of point-symmetric cells have been formed, all the active areas and all the gate electrodes are aligned in one direction, which produces an easy-to-process pattern. As a result, variations in the gate width and gate length of each transistor are alleviated, which reduces a variation in the threshold value.

In a further miniaturized transistor, a variation in the threshold value due to a fluctuation in the density of dopant contributing to the other variation in the threshold value is becoming predominant and measures from the viewpoint of worked surfaces are approaching their limit. Therefore, it is becoming difficult to reduce the memory size further and make an SRAM operate on a still lower voltage.

Jpn. Pat. Appln. KOKAI Publication No. 2005-302231 has disclosed that a read-only transfer gate and a read driver transistor are added to a 6-transistor memory cell. With this configuration, the stability of the stored data is improved and the cell current becomes larger and therefore the operating speed becomes faster.

### BRIEF SUMMARY OF THE INVENTION

According to a first aspect of the invention, there is provided a semiconductor memory device comprising: a memory cell array which has a plurality of memory cells arranged in a matrix; a plurality of word lines which are connected to a plurality of memory cells in each of the rows of the memory cell array; and a first and a second bit line for writing and a third bit line for reading which are connected to a plurality of memory cells in each of the columns of the memory cell array, each of the memory cells including a first inverter which includes a first transistor for loading and a second transistor for driving and has an input node and an output node, a second inverter which includes a third transistor for loading and a fourth transistor for driving and has an input node and an output node, the input node and output node being connected to the output node and input node of the first inverter respectively, a fifth transistor which has a source and a drain region and a gate electrode, one of the source and drain regions being connected to the output node of the first inverter and the gate electrode being connected to the word line, a sixth transistor which has a source and a drain region and a gate electrode, one of the source and drain regions being connected to the output node of the second inverter and the gate electrode being connected to the word line, a seventh transistor which has a source and a drain region and a gate electrode, one of the source and drain regions being connected to the other of the source and drain regions of the fifth transistor and the other of the source and drain regions being connected to a node of a reference potential, and the gate electrode being connected to the first bit line, an eighth transistor which has a source and a drain region and a gate electrode, one of the source and drain regions being connected to the other of the source and drain regions of the sixth transistor, the other of the source and drain regions being connected to the node of the reference potential, and the gate electrode being connected to the second bit line, a ninth transistor which has a source and a drain region and a gate electrode, one of the source and drain regions being connected to the third bit line and the gate electrode being connected to the word line, and a tenth transistor which has a source and a drain region and a gate electrode, one of the source and drain regions being connected to the other of the source and drain regions of the ninth transistor, the other of the source and drain regions being connected to the node of the reference potential, and the gate electrode being connected to the output node of the first inverter, the first transistor, second transistor, fifth transistor, and seventh transistor being provided in a first area on a semiconductor substrate, the third transistor being provided in a second area on the semiconductor substrate adjacent to the first area, the fourth transistor, sixth transistor, and eighth transistor being provided in a third area on the semiconductor substrate, and the ninth transistor and tenth transistor being provided in a fourth area on the semiconductor substrate located between the second area and the third area.

According to a second aspect of the invention, there is provided a semiconductor memory device comprising: a memory cell array which has a plurality of memory cells arranged in a matrix; a plurality of word lines which are connected to a plurality of memory cells in each of the rows of the memory cell array; and a first and a second bit line for writing and a third and a fourth bit line for reading which are connected to a plurality of memory cells in each of the columns of the memory cell array, each of the memory cells including a first inverter which includes a first transistor for loading and a second transistor for driving and has an input node and an output node, a second inverter which includes a third transistor for loading and a fourth transistor for driving and has an input node and an output node, the input node and output node being connected to the output node and input node of the first inverter respectively, a fifth transistor which has a source and a drain region and a gate electrode, one of the source and drain regions being connected to the output node of the first inverter and the gate electrode being connected to the word line, a sixth transistor which has a source and a drain region and a gate electrode, one of the source and drain regions being connected to the output node of the second inverter and the gate electrode being connected to the word line, a seventh transistor which has a source and a drain region and a gate electrode, one of the source and drain regions being connected to the other of the source and drain regions of the fifth transistor and the other of the source and drain regions being connected to a node of a reference potential, and the gate electrode being connected to the first bit line, an eighth transistor which has a source and a drain region and a gate electrode, one of the source and drain regions being connected to the other of the source and drain regions of the sixth transistor, the other of the source and drain regions being connected to the node of the reference potential, and the gate electrode being connected to the second bit line, a ninth transistor which has a source and a drain region and a gate electrode, one of the source and drain regions being connected to the third bit line and the gate electrode being connected to the word line, a tenth transistor which has a source and a drain region and a gate electrode, one of the source and drain regions being connected to the other of the source and drain regions of the ninth transistor, the other of the source and drain regions being connected to the node of the reference potential, and the gate electrode being connected to the output node of the second inverter, an eleventh transistor which has a source and a drain region and a gate electrode, one of the source and drain regions being connected to the fourth bit line and the gate electrode being connected to the word line, and a twelfth transistor which has a source and a drain region and a gate electrode, one of the source and drain regions being connected to the other of the source and drain regions of the eleventh transistor, the other of the source and drain regions being connected to the node of the reference potential, and the gate electrode being connected to the output node of the first inverter.

### BRIEF DESCRIPTION OF THE SEVERAL VIEWS OF THE DRAWING

FIG. 1 is a circuit diagram of a semiconductor memory device according to a first embodiment of the invention;

FIG. 2 is a circuit diagram showing an example of a memory cell used in the memory device of FIG. 1;

FIG. 3 is a plan view showing the layout of the memory cell of FIG. 2;

FIG. 4 shows the way the corners of a pattern of the active area of a transistor get rounded for a lithographic reason when the layout of FIG. 3 is used;

FIG. 5 is a circuit diagram showing another example of a memory cell used in the memory device of FIG. 1;

FIG. 6 is a circuit diagram of a semiconductor memory device according to a second embodiment of the invention;

FIG. 7 is a circuit diagram showing an example of a memory cell used in the memory device of FIG. 6;

FIG. 8 is a plan view showing the layout of the memory cell of FIG. 7;

FIG. 9 is a circuit diagram showing another example of a memory cell used in the memory device of FIG. 7;

FIG. 10 is a circuit diagram showing still another example of a memory cell used in the memory device of FIG. 7;

FIG. 11 is a plan view showing an example of a pattern when the memory device of FIG. 8 using the memory cell of FIG. 10 is laid out on a semiconductor chip; and

FIG. 12 is a plan view schematically showing a pattern of a wider area than in FIG. 11.

### DETAILED DESCRIPTION OF THE INVENTION

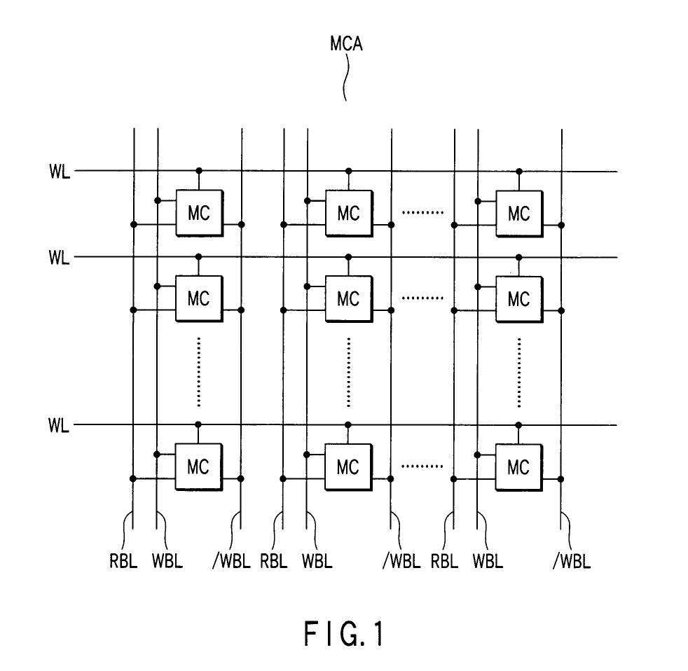

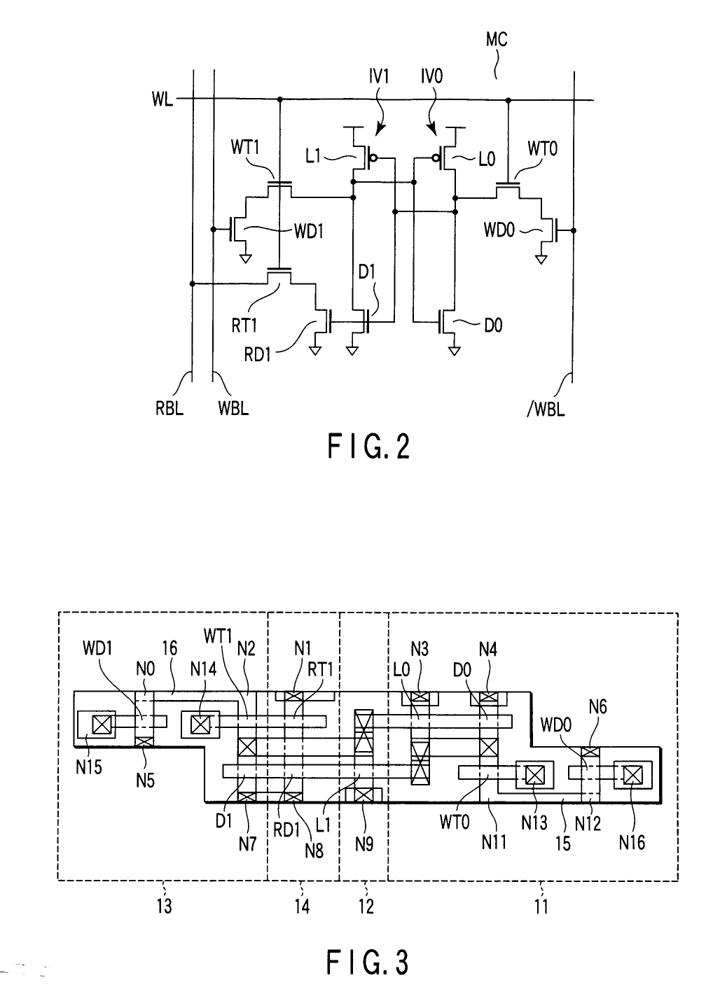

The specification related to Jpn. Pat. Appln. KOKAI Publication No. 2006-042704 filed on Feb. 20, 2006 in Japan by the assignor has disclosed a 10-transistor memory cell which has eliminated disturbances in the unselected cells in a read and a write operation by measures for circuitry and improved the SNM remarkably. FIG. 1 is a circuit diagram of a semiconductor memory device. FIG. 2 shows a single memory cell in a memory cell array.

As shown in FIG. 1, a semiconductor memory device has a memory cell array MCA including a plurality of memory cells MC arranged in a matrix. There are provided a plurality of word lines WL and a plurality of bit lines. The plurality of bit lines include two types of bit lines: data writing complementary bit lines WBL, /WBL and data reading bit lines RBL.

Each of the plurality of word lines is connected to a plurality of memory cells MC in each row of the memory cell array MCA. Each of the plurality of bit lines WBL, /WBL, RBL is connected to a plurality of memory cells MC in each column of the memory cell array MCA.

As shown in FIG. 2, each of the plurality of memory cells MC is composed of an inverter IV0, an inverter IV1 whose input node and output node are cross-coupled with the inverter IV0 so as to constitute a data latch circuit, and transistors WT0 and WT1, WD0 and WD1, RT1 and RD1 each of which is an NMOS transistor.

The inverter IV0 has a load PMOS transistor L0 and a driving (driver) NMOS transistor D0. Similarly, the inverter IV1 has a load PMOS transistor L1 and a driving NMOS transistor D1.

The transistors WT0 and WT1 are write transfer gate transistors which write data into a data latch circuit. The transistors WD0 and WD1 are write transfer gate transistors which transfer data in writing data into a data latch circuit. The transistor RT1 is a read transfer gate transistor which transfers data in reading the data from a data latch circuit. The transistor RD1 is a read driver transistor which reads the data from a data latch circuit.

One of the source and drain regions of the transistor WT0 is connected to the output node of the inverter IV0 and the gate electrode is connected to a word line WL. Similarly, one of the source and drain regions of the transistor WT1 is connected to the output node of the inverter IV1 and the gate electrode is connected to a word line WL.

One of the source and drain regions of the transistor WD0 is connected to the other of the source and drain regions of the transistor WT0. The other of the source and drain regions of the transistor WD0 is connected to a reference potential VSS. The gate electrode of the transistor WD0 is connected to a bit line /WBL. Similarly, one of the source and drain regions of the transistor WD1 is connected to the other of the source and drain regions of the transistor WT1. The other of the source and drain regions of the transistor WD1 is connected to the reference potential VSS. The gate electrode of the transistor WD1 is connected to a bit line WBL.

One of the source and drain regions of the transistor RT1 is connected to a bit line RBL. The gate electrode of the transistor RT1 is connected to a word line WL. One of the source and drain regions of the transistor RD1 is connected to the other of the source and drain regions of the transistor RT1. The other of the source and drain regions of the transistor RD1 is connected to the reference potential VSS. The gate of the transistor RD1 is connected to the output node of the inverter IV0.

The operation of the memory cell of FIG. 2 will be explained briefly. When data is written into a memory cell, a word line WL is selected and complementary-level write data are supplied to data write bit lines WBL, /WBL. At this time, the transistors WT0 and WT1 are turned on, thereby turning on either the transistor WD0 or WD1 according to the complementary data on the bit lines WBL, /WBL, which writes data into the data latch circuit.

When the data is read from the memory cell, the word line WL is selected and the data writing bit lines WBL, /WBL are both made low. At this time, the transistor RT1 goes on, enabling the transistor RD1 to go on or off according to the stored data in the data latch circuit, which causes the stored data in the data latch circuit to be read onto the reading bit line RBL.

In the memory cell of FIG. 2, even when the word line WL has been selected and the transistors WT0 and WT1 are turned on in writing data and reading the data from the memory cell, a pair of storage holding nodes of the data latch circuit is not connected to the data writing bit lines WBL, /WBL. That is, since the data latch circuit is not disturbed by bit line noise, the SNM is improved remarkably.

When the 10-transistor memory cell shown in FIG. 2 is actually laid out, it is desirable to devise means of preventing the pattern area from increasing. Since in the 10-transistor memory cell shown in FIG. 2, data is read onto a single bit line RBL in reading data, this is effective when the number of memory cells connected to the bit line RBL is small.

However, as the number of memory cells connected to the bit line RBL increases, a method of reading data by a differential method as in the aforementioned conventional 6-transistor memory cell may be effective.

### First Embodiment

FIG. 3 schematically shows the layout of the memory cell of FIG. 2. FIG. 3 shows the source region/drain region/gate region (active area), polysilicon interconnect, contacts, metal interconnects, and others of a transistor formed on a semiconductor substrate. As shown in FIG. 3, transistors L0, D0, WT0, WD0 are arranged in a first area 11 on the semiconductor substrate. A transistor L1 is arranged a second area 12 adjacent to the first area 11. Moreover, transistors D1, WT1, and WD1 are arranged in a third area 13. Transistor RT1 and transistor RD1 are arranged in a fourth area 14 located between the second area 12 and the third area 13.

The other of the source and drain regions of the transistor WT0 and one of the source and drain regions of the transistor WD0 are connected to each other via a diffusion layer 15 arranged in the first area 11 on the semiconductor substrate. Similarly, the other of the source and drain regions of the transistor WT1 and one of the source and drain regions of the transistor WD1 are connected to each other via a diffusion layer 16 arranged in the third area 13 on the semiconductor substrate. In FIG. 3, N0 to N9, N11 to N16 each indicate circuit nodes.

With such a layout, the source node N12 of the transistor WD0 and node N11 in one of the source and drain regions of the transistor WT0 are connected to each other via the diffusion layer 15 without using an upper-layer metal interconnect. Similarly, the source node N0 of the transistor WD1 and node N2 in one of the source and drain regions of the transistor WT1 are connected to each other via the diffusion layer 16 without using an upper-layer metal interconnect. When node N0 and node N2 are connected to each other and node N11 and node N12 are connected to each other using an upper-layer metal interconnect, it is necessary to provide a via for connecting nodes to an upper-layer metal interconnect and an interconnect pattern composed of relay interconnect layers so as to correspond to nodes N0, N2 and nodes N11, N12. However, in the first embodiment, since node N0 and node N2 are connected to each other via a diffusion layer and node N11 and N12 are connected to each other via a diffusion layer, there is no limit to the arrangement of upper-layer metal interconnects, which enables an increase in the pattern area to be suppressed.

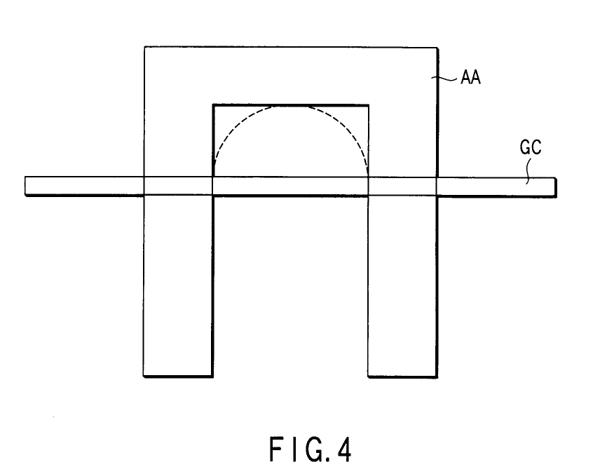

When the layout of FIG. 3 is used, it is impossible to extend all the active areas only in one direction. The layout has to be formed by extending in two directions: the longitudinal direction and the lateral direction. In this case, for a lithographic reason, for example, the corners of the pattern of the active area AA get rounded as shown in FIG. 4, which contributes to a variation in the gate width of a transistor close to the corners. In FIG. 4, GC indicates a gate interconnect. Such a variation in the transistor occurs at the transistors WD1, WT1, WD0, WT0 in the layout shown in FIG. 3. These transistors, however, do not constitute a data latch circuit in the memory cell. Accordingly, variations in the transistors have an effect on the analog performance parameters, including a cell current in the memory cell, but have no adverse effect on the SNM contributing to the malfunction of the memory cell. In contrast, as for the transistors L0, D0, L1, and D1 which constitute a data latch circuit in the memory cell and have an effect on the SNM, the individual source regions and the individual drain regions are formed in such a manner that they are arranged in the same direction on the semiconductor substrate. Consequently, the SNM is not adversely affected.

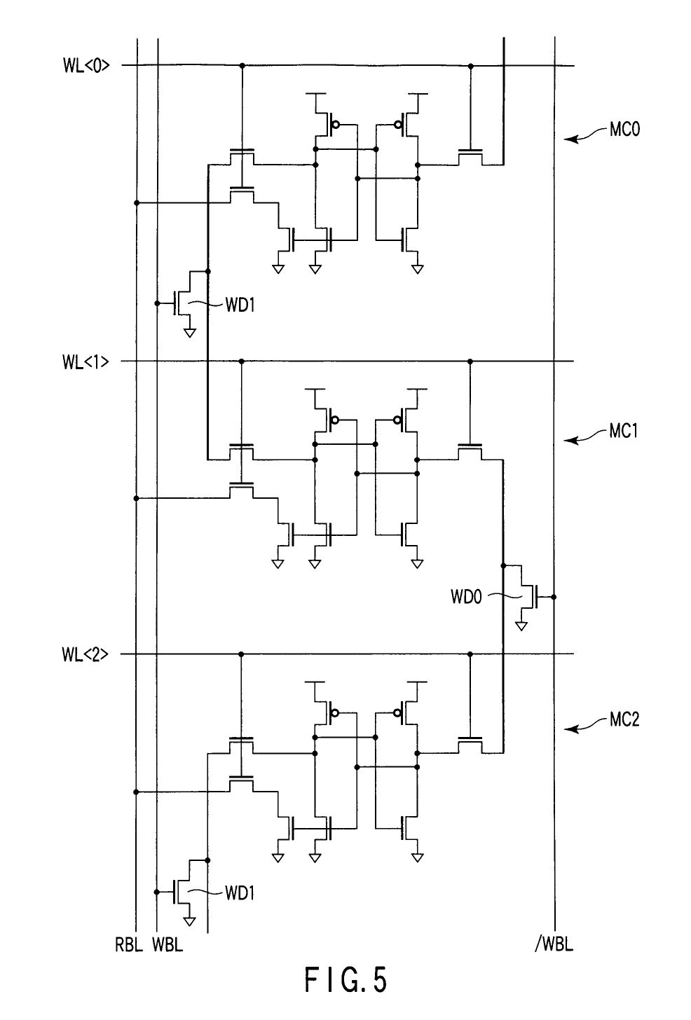

In the memory cell array of FIG. 1, when data is written into the selected memory cell, the word line WL in the selected row is made high, one of the data writing bit lines WBL, /WBL in the selected column is made low and the other is made high. At this time, in the write driver transistors WD0 and WD1, driving force, that is, the channel width of the transistor, has to be made larger in preparation for a case where the reverse of the stored data in the data latch circuit is written. Accordingly, the area of the memory cell increases that much. To improve this point, the memory cell has only to be improved as shown in FIG. 5.

FIG. 5 shows another example of memory cells used in the memory cell array of FIG. 1. In FIG. 5, three memory cells MC0, MC1, MC2 adjacent to one another in the column direction. Each of write driver transistors WD0 and WD1 are shared by two memory cells adjoining in the column direction. Specifically, the memory cell MC1 and the memory cell MC2 adjoining the memory cell on one side in the column direction share the write driver transistor WD0. Moreover, the memory cell MC1 and the memory cell MC0 adjoining the memory cell on the other side in the column direction share the write driver transistor WD1.

When the memory cell of FIG. 5 is used, the operation of writing data into the selected memory cell and the operation of reading data from the selected memory cell are the same as those in the memory cell shown in FIG. 2. In the memory cell of FIG. 5, two memory cells adjoining in the column direction share the write driver transistors WD0 and WD1. For this reason, when the size of the transistor WD0 and that of the transistor WD1 are made the same, the occupied area per cell of each of the transistors WD0 and WD1 can be halved. Accordingly, the memory cell of FIG. 5 produces the effect of decreasing the area of the memory cell. Furthermore, since the transistor WD1 provided in the memory cell MC0 and the transistor WD1 provided in the memory cell MC1 are shared with the memory cells MC0, MC1 for use as write driver transistors, double the driving force is obtained.

### Second Embodiment

In the first embodiment, since data is read onto a single bit line RBL when data is read from each memory cell, this is effective when the number of memory cells connected to a bit line RBL is small. However, as the number of memory cells connected to a bit line RBL increases, a differential method may be effective in reading data.

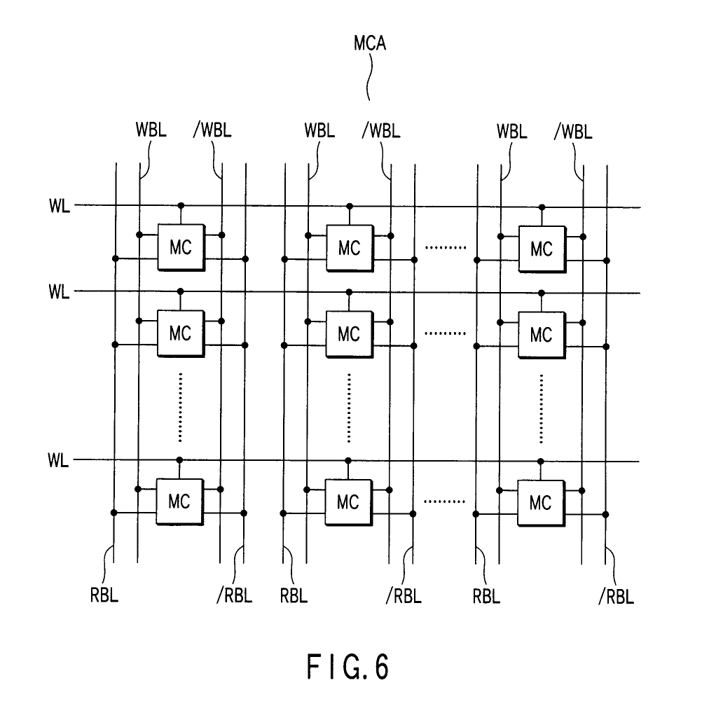

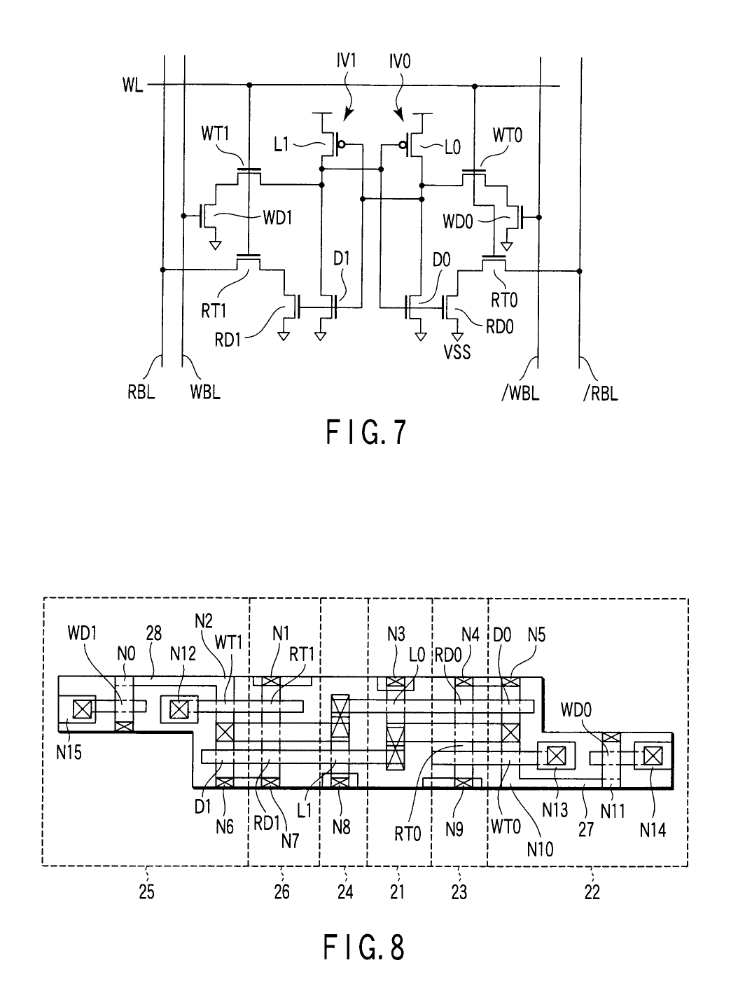

FIG. 6 is a circuit diagram of a semiconductor memory device according to a second embodiment of the invention. FIG. 7 shows a memory cell in the memory cell array of FIG. 6.

As shown in FIG. 6, there is provided a memory cell array MCA which has a plurality of memory cells MC arranged in a matrix. There are provided a plurality of word lines WL and a plurality of bit lines. The plurality of bit lines include two types of bit lines: data writing complementary bit lines WBL, /WBL and data reading complementary bit lines RBL, /RBL.

Each of the plurality of word lines WL is connected to a plurality of memory cells MC in each row of the memory cell array MCA. Each of the plurality of bit lines WBL, /WBL, RBL, /RBL is connected to a plurality of memory cells MC in each column of the memory cell array MCA.

The memory cell shown in FIG. 7 is composed of 12 transistors. Data is read from a data latch circuit onto two reading bit lines.

The memory cell of FIG. 7 differs from that of FIG. 2 in that a transistor TR0 for a read transfer gate, a transistor RD0 for a read driver, and a bit line /RBL for reading are added. The bit line /RBL makes a complementary pair with the bit line RBL.

One of the source and drain regions of the transistor RT0 is connected to a bit line /RBL. The gate electrode of the transistor RT0 is connected to a word line WL. One of the source and drain regions of the transistor RD0 is connected to the other of the source and drain regions of the transistor RT0. The other of the source and drain regions of the transistor RD0 is connected to a reference potential VSS. The gate electrode of the transistor RD0 is connected to the output node of an inverter IV1.

Next, the operation of writing data into the selected memory cell and the operation of reading the data from the selected memory cell will be explained. When data is written into a memory cell, the word line WL in the selected row is made high and one of the bit lines WBL and /WBL in the selected column is made low and the other is made high. All of the word lines WL in the unselected rows are made low and both of the bit lines WBL and /WBL in the unselected columns are made low. All of the data reading bit lines /RBL, RBL are made high.

Since the word line WL in the selected row is made high when data is written into the selected memory cell, the transistors WT0 and WT1 in all the memory cells connected to the word line WL in the same row as the selected memory cell are turned on.

However, since in the unselected memory cells connected to the word line in the selected row, both the bit lines WBL and /WBL have been made low and both the transistors WD0 and WD1 are off, the selected memory cell is not disturbed by the bit lines, which prevents the data from being destroyed.

The transistors RT0, RT1 in all the memory cells connected to the word line WL in the same row as the selected memory cell go into the on state. However, the data path composed of the transistors RT0, RT1 and the transistors RD0, RD1 connected in series with the transistors RT0, RT1 differs from the data path in writing data. That is, even when the transistors RT0, RT1 have been turned on, neither their source regions nor drain regions are connected to the data latch circuit, which prevents the high level of the bit lines /RBL, RBL from being transmitted to the data latch circuit and disturbing the stored data.

As seen from the above, in a memory cell array having the memory cell of FIG. 7, a write disturb problem occurring in a memory cell array having a conventional memory cell can be avoided. The write disturb problem is such that, when data is written, the data in a memory cell whose SNM is low and whose data stability is low among the unselected memory cells connected to the word line in the selected row is destroyed.

On the other hand, when the data is read from the selected memory cell, the word line WL in the selected row is made high, both the bit lines /RBL, RBL are made high, the word lines in the unselected rows are made low, and both the data reading bit lines /RBL, RBL in the unselected columns are made high. Moreover, all the data writing bit lines WBL and /WBL are made low. When data is read, a data path composed of transistors RD0, RD1 and transistors RT0, RT1 is used. The on and off state of the transistors RD0, RD1 of the selected cell is changed according to stored data. Differential data can be taken out onto the data reading bit lines /RBL, RBL.

In the semiconductor memory device of FIG. 6, when the data is read from the selected memory cell, the transistors RT0, RT1 in all the memory cells connected to the word line WL in the same row as the selected memory cell are turned on as when data is written. However, when transistors RT0, RT1 go into the on state, even if a memory cell whose SNM is low and whose data stability is low exists, there is no possibility that the high level of the data reading bit lines /RBL, RBL will be transmitted to the data latch circuit, having an effect on the data, since the neither the source regions and drain regions of the transistors RT0, RT1 are connected to the data latch circuit.

When data is read, the transistors WT0 and WT1 in all the memory cells connected to the word line WL in the same row as the selected memory cell are turned on as when data is written. However, since all the data writing bit lines WBL and /WBL are made low and both the transistors WD0 and WD1 are off, even if a memory cell whose SNM is low and whose data stability is low exists, the data can be prevented from being destroyed.

As described above, in the semiconductor memory device of FIG. 6, the problem encountered in a memory cell array using the conventional memory cell, that is, the read disturb problem, can be avoided.

FIG. 8 schematically shows the layout of the memory cell of FIG. 7. FIG. 8 shows the source region/drain region/gate region (active area) of a transistor, diffusion layer interconnects, metal interconnects, and others formed on a semiconductor substrate. In a memory cell, 12 transistors are halved. The two halved groups of transistors are arranged so as to be symmetric with respect to a point. Specifically, as shown in FIG. 8, a first group of transistors is composed of transistors L0, D0, WT0, WD0, RT0, RD0. A second group of transistors is composed of transistors L1, D1, WT1, WD1, RT1, RD1. The transistors in the first group and the transistors in the second group are arranged in positions on the semiconductor substrate so as to be symmetric with respect to a point. The transistor L0 is provided in a first area 21 on the semiconductor substrate. The transistors D0, WT0 are provided on a second area 22 on the semiconductor substrate. The transistors RT0, RD0 are provided in a third area 23 between the first area 21 and the second area 22 on the semiconductor substrate. The transistor L1 is provided in a fourth area 24 adjacent to the first area 21 on the semiconductor substrate. The transistors D1, WT1 are provided in a fifth area 25 on the semiconductor substrate. The transistors RT1, RD1 are provided in a sixth area 26 between the fourth area 24 and the fifth area 25 on the semiconductor substrate. The transistor WD0 is provided in the second area 22 and the transistor WD1 is provided in the fifth area 25.

The other of the source and drain regions of the transistor WT0 is connected to one of the source and drain regions of the transistor WD0 via a diffusion layer 27 provided in the second area 22 on the semiconductor substrate. Similarly, the other of the source and drain regions of the transistor WT1 is connected to one of the source and drain regions of the transistor WD1 via a diffusion layer 28 provided in the fifth area 25 on the semiconductor substrate.

Such a layout produces almost the same effect as that of the layout of the 10-transistor memory cell in the first embodiment described with reference to FIG. 3.

In the semiconductor memory device of FIG. 6, when data is written into the selected memory cell, the word line WL in the selected row is made high and one of the data writing bit lines WBL and /WBL in the selected column is made low and the other is made high according to the data to be written. At this time, in the transistors WD0 and WD1, driving force, that is, the channel width of the transistor, has to be made larger in preparation for a case where the reverse of the stored data in the data latch circuit is written. Accordingly, the area of the memory cell increases that much. A concrete example which has overcome this point will be explained below.

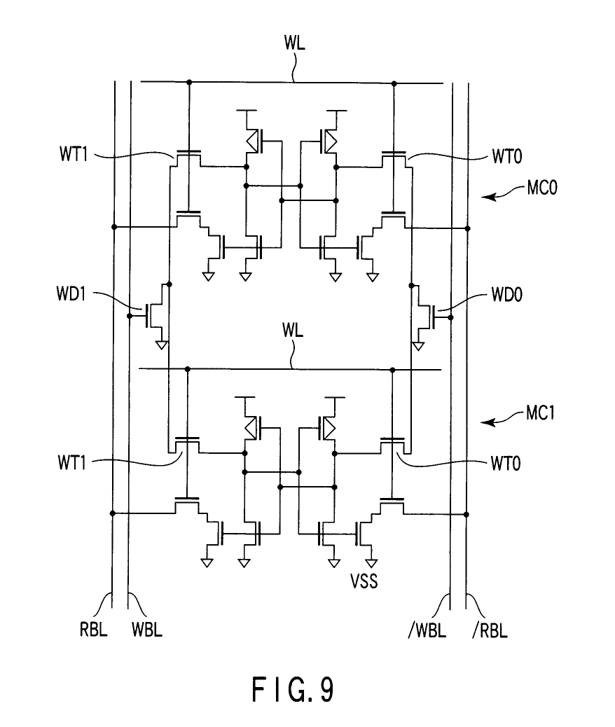

FIG. 9 shows another example of the circuit of memory cells used in the memory cell array of FIG. 6. FIG. 9 shows two memory cells MC0, MC1 adjacent to each other in the column direction. Write driver transistors WD0 and WD1 are shared by a plurality of memory cells in the same column including two memory cells MC0, MC1. Specifically, the other of the source and drain regions of the transistor WT0 in each of the memory cells is connected to a common junction node. Between the common junction node and a reference potential VSS, the source and drain regions of the write driver transistor WD0 are connected. Similarly, the other of the source and drain regions of the transistor WT1 in each of the memory cells is connected to a common junction node. Between the common junction node and the reference potential VSS, the source and drain regions of the write driver transistor WD1 are connected.

In FIG. 9, the operation of writing data into the selected memory cell and the operation of reading the data from the selected memory cell are the same as those of the memory cell shown in FIG. 7. Since in the memory cell of FIG. 9, the transistors WD0 and WD1 are shared by a plurality of (an n number of: n is an integer equal to or larger than 2) memory cells arranged in the same column, the effect of decreasing the area of the memory cell is obtained.

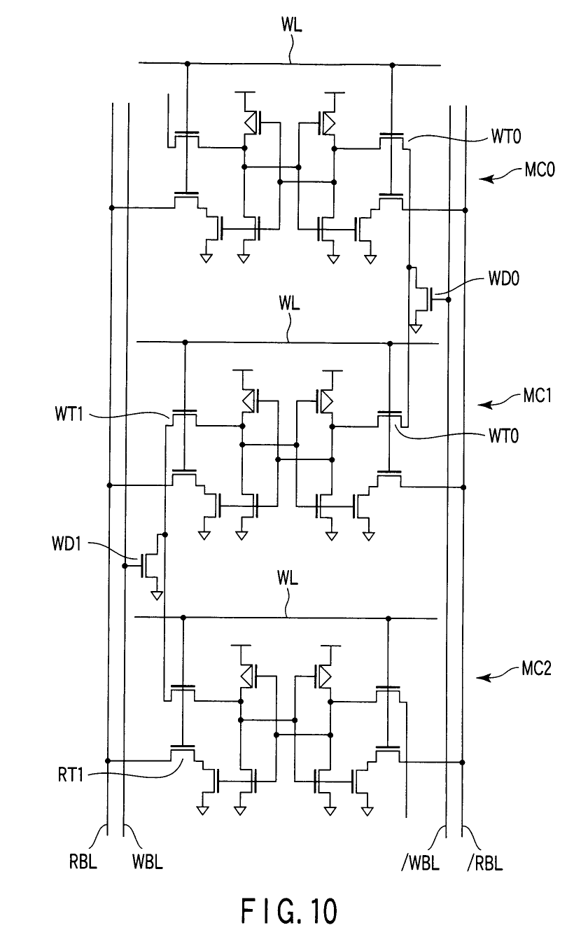

FIG. 10 shows still another example of the circuit of memory cells used in the memory cell array of FIG. 6. FIG. 10 shows three memory cells MC0, MC1, MC2 adjoining in the column direction. Each of write driver transistors WD0 and WD1 is shared by two memory cells adjoining in the column direction. Specifically, the memory cell MC1 and the memory cell MC2 adjacent to the memory cell MC1 in the downward direction (a first direction) share the write driver transistor WD0. The memory cell MC1 and the memory cell MC0 adjacent to the memory cell MC1 in the upward direction (a second direction) share the write driver transistor WD1.

In FIG. 10, the operation of writing data into the selected memory cell and the operation of reading the data from the selected memory cell are the same as those of the memory cell shown in FIG. 9. In the memory cell, since two memory cells adjoining in the column direction share the write driver transistors WD0 and WD1, when the transistors WD0 and WD1 are configured to have the same size, the occupied area per cell of the transistors WD0 and WD1 can be halved. Accordingly, the effect of decreasing the area of the memory cell is obtained. Moreover, since the write driver transistor provided in the memory cell MC0 and the write driver transistor provided in the memory cell MC1 are shared by the memory cells MC0, MC1, twice the driving force is obtained.

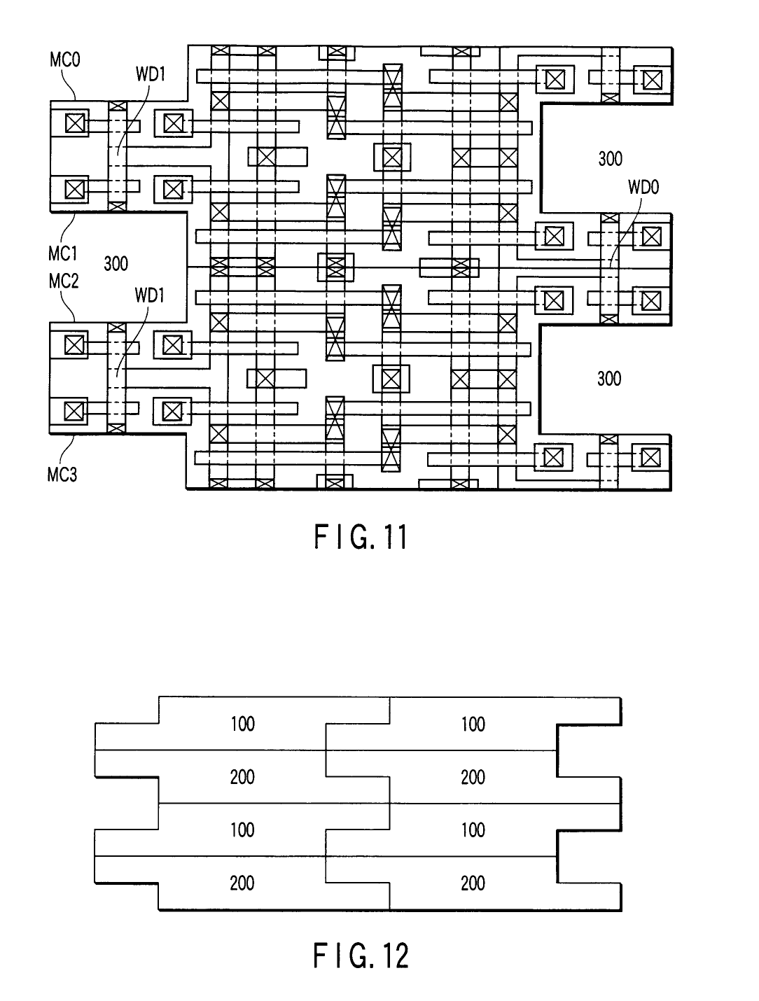

FIG. 11 shows a part of a memory cell array having the memory cells of FIG. 10 when the memory cell array has been actually laid out on a semiconductor chip. FIG. 11 shows only four memory cells MC0 to MC3 arranged in the column direction. In the region of each of the memory cells, two halved groups of transistors are arranged in point-symmetric positions as described above. The patterns of two memory cell regions adjoining in the vertical direction (the bit line direction or the column direction) in FIG. 11 have layouts turned over in the vertical direction (so as to be symmetric with respect to a line). Specifically, the region of the memory cell MC1 has a line-symmetric pattern layout with respect to the region of the memory cell MC0. The region of the memory cell MC2 has a line-symmetric pattern layout with respect to the region of the memory cell MC1. The region of the memory cell MC3 has a line-symmetric pattern layout with respect to the region of the memory cell MC2. The pattern layouts of the memory cells MC0 and MC2 are set in the same direction and the pattern layouts of the memory cells MC1 and MC3 are set in the same direction. Having such layouts provides the advantages of sharing the power supply lines and the contacts connected to the bit lines at the boundary between the memory cell regions and decreasing the cell area.

Furthermore, since in two memory cells adjoining in the column direction, for example, in the regions of the memory cells MC0 and MC1, the write driver transistor WD1 is shared, and in two memory cells adjoining in the column direction, for example, in the regions of the memory cells MC1 and MC2, the write driver transistor WD0 is shared, the memory cell area can be decreased. In the regions where the transistors WD0, WD1 have been formed, the individual transistors are connected in parallel.

In each of the memory cell regions, the one unconnected with the reference potential VSS of the source and drain regions of the transistor WD0 and the one unconnected with the reference potential VSS of the source and drain regions of the transistor WD1 are symmetric with respect to a point. For example, in the region of the memory cell MC1, the region unconnected to the reference potential VSS of the source and drain regions of the write driver transistor WD0 is provided in the lower right part of the memory cell region in FIG. 11 and the region unconnected to the reference potential VSS of the source and drain regions of the write driver transistor WD1 is provided in the upper left of the memory cell region in FIG. 11. In the memory cell MC0 adjacent upward to the memory cell MC1, the region unconnected to the reference potential VSS of the source and drain regions of the write driver transistor WD1 is provided in the lower left part of the memory cell region of the memory cell MC0 in FIG. 11 and the region unconnected to the reference potential VSS of the source and drain regions of the write driver transistor WD0 is provided in the upper right part of the memory cell region in FIG. 11. Moreover, in the memory cell MC2 adjacent downward to the memory cell MC1, the region unconnected to the reference potential VSS of the source and drain regions of the write driver transistor WD0 is provided in the upper right part of the memory cell region in FIG. 11 and the region unconnected to the reference potential VSS of the source and drain regions of the write driver transistor WD1 is provided in the lower left part of the memory cell region in FIG. 11.

Then, as shown in FIG. 12, a first memory cell region 100 having a first pattern layout the same as that of the memory cells MC0, MC2 and a second memory cell region 200 having a second pattern layout the same as that of the memory cells MC1, MC3 line-symmetric with respect to the first pattern layout are arranged alternately in the column direction. Moreover, a row in which the first memory cell region 100 is repeated consecutively in the row direction and a row in which the second memory cell region 200 is repeated consecutively in the row direction are arranged alternately in the column direction.

As shown in FIGS. 11 and 12, the region where the write driver transistor shared by two memory cell regions adjoining in the column direction has been formed has such a pattern as projects to one side in the row direction. For example, the region where the write driver transistor WD1 shared by the two memory cell regions of the memory cells MC0 and MC1 has been formed has such a pattern as projects to the left side in the row direction. The region where the write driver transistor WD0 shared by the two memory cell regions of the memory cells MC1 and MC2 has been formed has such a pattern as projects to the right side in the row direction. Consequently, an empty region 300 occurs between the two projection pattern regions projecting to the right side or the left side in the row direction.

To overcome this problem, a plurality of memory cell columns are arranged in such a manner that the projection pattern region of the memory cell region in a memory cell column goes into the empty region 300 of the memory cell region in another memory cell column adjacent to the memory cell column as shown in FIG. 12. This enables a large number of memory cell regions to be arranged leaving no space between them, which prevents a dead space from developing in the pattern layout of the memory cell array.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a memory cell array which has a plurality of memory cells arranged in a matrix;
a plurality of word lines which are connected to a plurality of memory cells in each of the rows of the memory cell array; and
a first and a second bit line for writing and a third bit line for reading which are connected to a plurality of memory cells in each of the columns of the memory cell array,
each of the memory cells including
a first inverter which includes a first transistor for loading and a second transistor for driving and has an input node and an output node,
a second inverter which includes a third transistor for loading and a fourth transistor for driving and has an input node and an output node, the input node and output node being connected to the output node and input node of the first inverter respectively,
a fifth transistor which has a source and a drain region and a gate electrode, one of the source and drain regions being connected to the output node of the first inverter and the gate electrode being connected to the word line,
a sixth transistor which has a source and a drain region and a gate electrode, one of the source and drain regions being connected to the output node of the second inverter and the gate electrode being connected to the word line,
a seventh transistor which has a source and a drain region and a gate electrode, one of the source and drain regions being connected to the other of the source and drain regions of the fifth transistor and the other of the source and drain regions being connected to a node of a reference potential, and the gate electrode being connected to the first bit line,
an eighth transistor which has a source and a drain region and a gate electrode, one of the source and drain regions being connected to the other of the source and drain regions of the sixth transistor, the other of the source and drain regions being connected to the node of the reference potential, and the gate electrode being connected to the second bit line,
a ninth transistor which has a source and a drain region and a gate electrode, one of the source and drain regions being connected to the third bit line and the gate electrode being connected to the word line, and
a tenth transistor which has a source and a drain region and a gate electrode, one of the source and drain regions being connected to the other of the source and drain regions of the ninth transistor, the other of the source and drain regions being connected to the node of the reference potential, and the gate electrode being connected to the output node of the first inverter,
the first transistor, second transistor, fifth transistor, and seventh transistor being provided in a first area on a semiconductor substrate,
the third transistor being provided in a second area on the semiconductor substrate adjacent to the first area,
the fourth transistor, sixth transistor, and eighth transistor being provided in a third area on the semiconductor substrate, and
the ninth transistor and tenth transistor being provided in a fourth area on the semiconductor substrate located between the second area and the third area.

2. The semiconductor memory device according to claim 1, further comprising:
a first diffusion layer which electrically connects the other of the source and drain regions of the fifth transistor and one of the source and drain regions of the seventh transistor and is formed in the first area; and
a second diffusion layer which electrically connects the other of the source and drain regions of the sixth transistor and one of the source and drain regions of the eighth transistor and is formed in the third area.

3. The semiconductor memory device according to claim 1, wherein the source region and drain region of each of the first transistor, second transistor, third transistor, and fourth transistor are formed on the semiconductor substrate, and are arranged in the same direction.

4. A semiconductor memory device comprising:
a memory cell array which has a plurality of memory cells arranged in a matrix;
a plurality of word lines which are connected to a plurality of memory cells in each of the rows of the memory cell array; and
a first and a second bit line for writing and a third and a fourth bit line for reading which are connected to a plurality of memory cells in each of the columns of the memory cell array,
each of the memory cells including
a first inverter which includes a first transistor for loading and a second transistor for driving and has an input node and an output node,
a second inverter which includes a third transistor for loading and a fourth transistor for driving and has an input node and an output node, the input node and output node being connected to the output node and input node of the first inverter respectively,
a fifth transistor which has a source and a drain region and a gate electrode, one of the source and drain regions being connected to the output node of the first inverter and the gate electrode being connected to the word line,
a sixth transistor which has a source and a drain region and a gate electrode, one of the source and drain regions being connected to the output node of the second inverter and the gate electrode being connected to the word line,
a seventh transistor which has a source and a drain region and a gate electrode, one of the source and drain regions being connected to the other of the source and drain regions of the fifth transistor and the other of the source and drain regions being connected to a node of a reference potential, and the gate electrode being connected to the first bit line,
an eighth transistor which has a source and a drain region and a gate electrode, one of the source and drain regions being connected to the other of the source and drain regions of the sixth transistor, the other of the source and drain regions being connected to the node of the reference potential, and the gate electrode being connected to the second bit line,
a ninth transistor which has a source and a drain region and a gate electrode, one of the source and drain regions being connected to the third bit line and the gate electrode being connected to the word line,
a tenth transistor which has a source and a drain region and a gate electrode, one of the source and drain regions being connected to the other of the source and drain regions of the ninth transistor, the other of the source and drain regions being connected to the node of the reference potential, and the gate electrode being connected to the output node of the second inverter,
an eleventh transistor which has a source and a drain region and a gate electrode, one of the source and drain regions being connected to the fourth bit line and the gate electrode being connected to the word line, and
a twelfth transistor which has a source and a drain region and a gate electrode, one of the source and drain regions being connected to the other of the source and drain regions of the eleventh transistor, the other of the source and drain regions being connected to the node of the reference potential, and the gate electrode being connected to the output node of the first inverter.

5. The semiconductor memory device according to claim 4, wherein the first to twelfth transistors are divided into a first group composed of the first, second, fifth, seventh, ninth, and tenth transistors and a second group composed of the third, fourth, sixth, eighth, eleventh, and twelfth transistors and the first, second, fifth, seventh, ninth, and tenth transistors in the first group and the third, fourth, sixth, eighth, eleventh, and twelfth transistors in the second group are arranged in positions on a semiconductor substrate, and are arranged symmetric with respect to a point.

6. The semiconductor memory device according to claim 5, wherein the first transistor is provided in a first area on the semiconductor substrate,
the second and fifth transistors are provided in a second area on the semiconductor substrate,
the ninth and tenth transistors are provided in a third area located between the first area and second area on the semiconductor substrate,
the third transistor is provided in a fourth area adjacent to the first area on the semiconductor substrate,
the fourth and sixth transistors are provided in a fifth area on the semiconductor substrate, and
the eleventh and twelfth transistors are provided in a sixth area located between the fourth area and fifth area on the semiconductor substrate.

7. The semiconductor memory device according to claim 6, wherein the seventh transistor is provided in the second area, and
the eighth transistor is provided in the fifth area.

8. The semiconductor memory device according to claim 4, further comprising:
a first diffusion layer which electrically connects the other of the source and drain regions of the fifth transistor and one of the source and drain regions of the seventh transistor and is formed in the second area, and
a second diffusion layer which electrically connects the other of the source and drain regions of the sixth transistor and one of the source and drain regions of the eighth transistor and is formed in the fifth area,

9. The semiconductor memory device according to claim 4, wherein each of the seventh transistors and each of the eighth transistors are shared by a plurality of memory cells arranged in each of the columns of the memory cell array.

10. The semiconductor memory device according to claim 9, wherein each of the seventh transistors is shared by two memory cells adjoining in the column direction among said plurality of memory cells, and each of the eighth transistors is shared by two memory cells adjoining in the column direction among said plurality of memory cells.

11. The semiconductor memory device according to claim 10, wherein each of the seventh transistors shared by the two memory cells has the source and drain regions connected in parallel, and
each of the eighth transistors shared by the two memory cells has the source and drain regions connected in parallel.

12. The semiconductor memory device according to claim 5, wherein the memory cell array has a plurality of first memory cell regions and a plurality of second memory cell regions, the first memory cell region having a first pattern layout and the second memory cell region having a second pattern layout line-symmetric with respect to the first pattern, and the first and second memory cell regions being arranged alternately in the column direction.

13. The semiconductor memory device according to claim 12, wherein in the memory cell array, a row in which the first memory cell region is repeated consecutively in the row direction and a row in which the second memory cell region is repeated consecutively in the row direction are arranged alternately in the column direction.

14. The semiconductor memory device according to claim 13, wherein the first and second memory cell regions include the seventh and eighth transistor formation regions, respectively,
the seventh transistor formation region in any one of said plurality of first memory cell regions and the seventh transistor formation region in the second memory cell region provided adjacent to one side of the first memory cell region in the column direction are provided to be adjacent to each other, and
the eighth transistor formation region in the first memory cell region and the eighth transistor formation region in the second memory cell region provided adjacent to the other side of the first memory cell in the column direction are provided so as to be adjacent to each other.
